(19) United States
(12) Patent Application Publication
(10) Pub. No.: US 2026/0153551 A1
(43) Pub. Date: Jun. 4, 2026

(54) Method and System for Identifying Discharge Hazards of Transmission Lines

(71) Applicant: ELECTRIC POWER RESEARCH INSTITUTE OF HAINAN POWER GRID CO., LTD., Haikou (CN)

(72) Inventors: Hailong ZHAO, Haikou (CN); Songling PANG, Haikou (CN); Qinzhu CHEN, Haikou (CN); Meiyi HUO, Haikou (CN); Ruien ZHANG, Haikou (CN); Liguo YANG, Haikou (CN); Chuangang CHEN, Haikou (CN)

(21) Appl. No.: 19/367,149

(22) Filed: Oct. 23, 2025

Related U.S. Application Data
(63) Continuation of application No. PCT/CN2024/141444, filed on Dec. 23, 2024.

(30) Foreign Application Priority Data
Nov. 29, 2024 (CN) 202411743224.1

(51) Int. Cl. G01R 31/08; G01R 19/00

(52) U.S. Cl. CPC G01R 31/085; G01R 19/0007; G01R 31/088

(57) ABSTRACT

The present invention relates to the field of power systems and automation, and discloses a method and system for identifying discharge hazards of transmission lines. The method comprises: acquiring and processing measured data of discharge hazards of the transmission lines, high-frequency discharge waveform data, and acquiring and discharge event data; creating a hazard identification requirement table and initializing same, and updating all elements in the table in the time sequence; looking up, for each newly acquired waveform segment, table to determine the operation and maintenance requirement, and performing comprehensive early warning on the hazard state of the lines.

### CROSS-REFERENCE TO RELATED APPLICATIONS

The present application is a continuation of International Application No. PCT/CN2024/141444, filed on Dec. 23, 2024, which claims priority to Chinese Patent Application No. 202411743224.1, titled “Method and System for Identifying Discharge Hazards of Transmission Lines”, filed on Nov. 29, 2024, the entire disclosure of which is incorporated herein by reference.

### TECHNICAL FIELD

The present invention relates to the field of power systems and automation, and particularly relates to a method and system for identifying discharge hazards of transmission lines.

### BACKGROUND

Transmission and distribution lines are susceptible to discharge hazards caused by factors such as insulator deterioration, contamination and floating foreign objects, which reduce the insulation strength between high-voltage side conductors and ground wires or towers at the ground potential. The discharge hazards will be developed into faults that ultimately cause line tripping and outage without timely clearance, resulting in significant economic losses and safety risks.

In order to accurately and promptly identify and eliminate discharges on lines, it is first necessary to detect the presence of discharge hazards and determine the types of discharge. Currently, most transmission and distribution lines of various voltage levels are equipped with distributed traveling wave fault location devices. By means of collecting, at both ends of lines, the high-frequency discharge traveling waves generated at and propagated from discharge points, features of the waves are calculated and compared to determine whether abnormal features are present, thereby identifying the existence and types of discharge and notifying line operation and maintenance personnel to carry out repair work.

When the issues of identification and classification of discharge hazards are solved in existing similar technologies, the main approach is to extract segments of high-frequency discharge waveform segments, calculate designated features such as amplitude, phase, and power-frequency-associated periodicity, apply pattern classification algorithms such as decision trees, support vector machines, or neural networks, and ultimately output a label indicating the presence or types of the hazards. However, in practice, potential hazards on transmission lines may arise from a variety of causes, and the development process of the hazards is not necessarily a linear increase to insulation breakdown and tripping. For example, smaller floating objects may cause early-stage discharge, but may fall off after being burned and carbonized in the discharge process, thereby terminating the discharge process. Therefore, during the extraction of single or multiple waveform segments in the prior art, when features are calculated, the abnormal development and accumulation of line hazards are not taken into account, the hazard state of lines cannot be determined throughout the process, the future development trend cannot be predicted, and accordingly, false alarms and missed detections are easy to occur.

### SUMMARY

In view of the above existing problems, potential hazards on transmission lines may arise from a variety of causes, and the development process of the hazards is not necessarily a linear increase to insulation breakdown and tripping. For example, smaller floating objects may cause early-stage discharge, but may fall off after being burned and carbonized in the discharge process, thereby terminating the discharge process. Therefore, during the extraction of single or multiple waveform segments in the prior art, when features are calculated, the abnormal development and accumulation of line hazards are not taken into account, the hazard state of lines cannot be determined throughout the process, the future development trend cannot be predicted, and accordingly, false alarms and missed detections are easy to occur.

To solve the above technical problems, the present invention discloses a method for identifying discharge hazards of transmission lines, comprising: acquiring measured data of discharge hazards of the transmission lines, acquiring and processing hazard high-frequency discharge waveform data of the transmission lines, and
acquiring and processing discharge hazard event data of the transmission lines; creating a hazard identification requirement table and initializing same, and updating all elements in the table in the time sequence; looking up, for each newly acquired waveform segment, the table to determine the operation and maintenance requirement level corresponding to the newly acquired discharge waveform, and performing comprehensive determination and early warning on the hazard state of the lines.

As a preferred scheme of the method for identifying the discharge hazards of the transmission lines of the present invention, wherein the acquiring measured data of discharge hazards of the transmission lines includes acquiring the hazard high-frequency discharge waveform data and the discharge hazard event data.
the hazard high-frequency discharge waveform data comprises segmenting the hazard high-frequency discharge waveform data into N short waveforms every 10 ms, i.e., half a power-frequency cycle, and calculating F key features Z₁ . . . . Zᵢ . . . . Z_{F} for each short waveform, wherein Z₁ is the maximum amplitude in the short waveform, Z_{F} is the power-frequency phase at which the maximum amplitude occurs; the maximum value Z_{i,max} and the minimum value Z_{i,min} are extracted from the current feature set of all short waveforms for each feature Zᵢ; the maximum Z_{1,max} and minimum values Z_{1,min} among the amplitudes of all short waveforms are and for the amplitude feature Z₁, wherein (1)-(n) are the numbers of the short waveforms:

$${Z}_{i , max} = max ( {Z}_{i} ( 1 ) , {Z}_{i} ( 2 ) , … , {Z}_{i} ( n ) )$$

$${Z}_{i , min} = min ( {Z}_{i} ( 1 ) , {Z}_{i} ( 2 ) , … , {Z}_{i} ( n ) )$$

discretization intervals are created to equally divide the range from the minimum value to the maximum value into Yᵢ intervals based on the minimum and maximum of each feature Zᵢ:

$$[ {Z}_{i , min} , {Z}_{i , min} + {Z}_{id} ) , [ \text{} {Z}_{i , min} + {Z}_{id} , \text{} {Z}_{i , min} + 2 \times {Z}_{id} ) , \text{} … , [ \text{} {Z}_{i , min} ( {Y}_{{i}^{-}} 1 ) \times {Z}_{id} , \text{} {Z}_{i , max} ]$$

$${Z}_{id} = ( {Z}_{i , {max}^{-}} {Z}_{i , min} ) / {Y}_{i}$$

Where, Z_{id} is the interval width.

The sum of the quantities of all the intervals for all the features is recorded as N,N=Y₁+Y₂+ . . . . Yᵢ+ . . . +Y_{F}, and an interval number set S=[1, 2, . . . , N], a total of N elements, is created, where each element is corresponding to a discretization interval.
the key feature of each short waveform, the i-th feature Zᵢ(n) of the n-th short waveform, is converted into the corresponding S value of the interval; and a new feature interval matrix C is formed based on the interval S values generated by all F features of all n waveforms:

$$\text{?} = [ \begin{matrix}{S}_{1 ( 1 )} & {S}_{1 ( 2 )} & … & {S}_{1 ( n )} \\ {S}_{2 ( 1 )} & {S}_{2 ( 2 )} & … & {S}_{2 ( n )} \\ … & … & … & … \\ {S}_{F ( 1 )} & {S}_{F ( 2 )} & … & {S}_{F ( n )}\end{matrix} ]$$

$$\text{?} \text{indicates text missing or illegible when filed}$$

each column of the matrix C represents the feature interval corresponding to all the features of one waveform, and each row represents the feature interval of all waveforms under any one feature type, the columns are arranged in the sequence of waveform acquisition, and the acquisition time of the left column is earlier than the waveform acquisition time represented by the right column for the waveform represented by the left column.

As a preferred scheme of the method for identifying the discharge hazards of the transmission lines of the present invention, wherein the discharge hazard event data comprises acquiring a set W=[W₁, W₂, . . . , Wₘ] of the discharge hazard event data of the transmission lines, where, 1-m are the number of the data, the time span covered by the data includes the time span covered by the discharge waveform data, the waveforms correspond to the known hazard events within the time: W₁ is the initiation of discharge caused by contamination accumulation on an insulator; W₂ is the further intensified discharge caused by burning of a suspended foreign object and the initiation of discharge due to excessive vegetation height; W₃ is the fault tripping caused by insulator degradation and failure; and W₄ is the clearance of a fault and the restoration of power supply by patrol personnel.

The hazard severity level sequence data includes a hazard severity level quantification value E, within the range of 0-4, assigned to each known hazard event in accordance with actual line operation and maintenance requirements, with the level range set in a range of 0, 1, 2, and 3: E=0 indicates no discharge hazard phenomenon.

E=1 indicates slight discharge, requiring continued monitoring.

E=2 indicates moderate discharge, which will cause flashover tripping and require partial inspection during line patrol.

E=3 indicates very severe discharge, which has already caused fault tripping and requires immediate proactive repair.

W₁ is the initiation of discharge caused by contamination accumulation on an insulator, belonging to the early-stage hazard with slight level, E₁=1.

W₂ is the further intensified discharge caused by burning of a suspended foreign object and the initiation of discharge due to excessive vegetation height, resulting in a fault over an extended period, E₂=2.

W₃ is the fault tripping caused by insulator degradation and failure, which has already caused tripping and requires immediate repair, E₃=3.

W₄ is the clearance of a fault and the restoration of power supply by patrol personnel, in which hazards are eliminated and there are no events, E₄=0.
the hazard level sequence formed is E=[1, 2, 3, 0].

As a preferred scheme of the method for identifying the discharge hazards of the transmission lines, where the acquiring and processing discharge hazard event data of the transmission lines comprises evaluating the activity of the hazard events based on the discharge interval through a system identification model:

$$f ( t ) = {\int }_{{t}_{1}}^{{t}_{2}} ( {\sum }_{j = 1}^{J} E \cdot \frac{{e}^{- {λ}_{j} ( t - {t}_{j} )}}{{λ}_{j}} ) d t + {\int }_{{t}_{1}}^{{t}_{2}} Φ ( \frac{Δ ( {t}^{′} ) - \overline{Δ}}{{σ}_{Δ}} ) {dt}^{′}$$

where n represents the number of discharge events occurring within the evaluation period, E is the severity level of the hazard events, λⱼ is the attenuation rate of the j-th discharge event, t₁ and t₂ are the start and end time of the evaluation period, tⱼ is the time at which the j-th discharge event occurs, Φ represents the standardization of the discharge interval difference, Δ(t′) represents the discharge interval at time t′, Δ̅ represents the average of the discharge interval, and σ_{Δ} represents the standard deviation of the discharge interval.

When Φ stabilizes between 0.45 and 0.55, the frequency and severity of discharge events are consistent with the average level, requiring continued monitoring. When Φ exceeds 0.55, the discharge interval is longer than the average time, the flash of a green light indicates that the activity of the hazard event is weakening.

When Φ is lower than 0.45, the discharge interval is shorter than the average time, and an A-level alarm is made, indicating that the activity of the current hazard event is increasing.
when F(t) decreases, the discharge event occurs but at a reduced frequency, indicating that the hazard event has been accumulated over a long period and may result in a fault of a transmission line, and a B-level alarm is made for hazard identification requirements to notify workers to conduct maintenance and inspection;
when F(t) increases, the discharge event occur frequently, indicating that the development of the current hazard event in a short term may cause a transmission line fault, and a D-level alarm is made to create current hazard identification requirements for the current hazard events and perform immediate repair.

As a preferred scheme of the method for identifying the discharge hazards of the transmission lines, wherein the creating a hazard identification requirement table includes the following rule for the hazard identification requirement table: the table includes a rows and b columns, where a is the number of feature intervals derived from discharge hazard waveform data, b is the number of discharge severity level derived from discharge hazard event data, and the initial values of all elements are the corresponding level value E in the columns where the elements are located. when a particular feature of the waveform falls within the feature interval represented by a, the discharge severity level at the current moment is the operation and maintenance requirement level represented by b. The maximum value in the current row represents the most urgent operation and maintenance action for the current feature interval. When F>1, i.e., the same waveform includes multiple features, the maximum values of all rows are compared, and the largest value is taken as the operation and maintenance requirement level of the current waveform;

The earliest collected short waveform u and the waveform v at the next time are collected based on the feature interval matrix C. In combination with the hazard identification requirement table, the feature interval value Sᵢ(u) of the feature i of the waveform u represents the row, while the corresponding value Eu of the waveform represents the column. The element at the intersection of the row Sᵢ(u) and the column Eu in the table represents the operation and maintenance requirement level of the feature i of the waveform u with the corresponding discharge level Eu, denoted table element as T (Sᵢ(u), Eu).
the table element T′ (Sᵢ(u), Eu) is updated for each feature i:

$${T}^{′} ( {S}_{i} ( u ) , Eu ) = 0.9 \times T ( {S}_{i} ( u ) , Eu ) + 0.8 \times ( Ev - T ( {S}_{i} ( u ) , Eu ) )$$

Where 0.9 represents the guiding effect of historical identical discharge hazard features on labeling the hazard severity of added discharge, and 0.8 represents the predictive significance of future discharge hazards within the same discharge waveform in labeling the current severity.
in the acquisition time sequence, each waveform and the waveform at the next time in the subsequent time are updated in table elements, until all the waveforms are processed and the table is fully filled.

As a preferred scheme of the method for identifying the discharge hazards of the transmission lines, wherein the comprehensive determination and early warning on the hazard state of the lines comprises calculating the current hazard value Hd:

$$H d = \frac{{\int }_{0}^{D} B \cdot {{e}^{-}}^{α t}}{Norm {\sum }_{m = 1}^{M} Filter ( {d}_{m} , β )}$$

The larger Hd indicates the more severe hazard, the smaller Hd indicates the less severe hazard, where B represents the discharge amplitude, dₘ represents the discharge waveform, M represents the number of waveform parameters, α and β are parameters adjusted according to actual conditions to control the intensity of exponential attenuation and information filtering, Norm represents the normalization of the summation result, and Filter is used for filtering waveform shape parameters;
the comprehensive condition of the transmission lines is determined after predicting that the long-term accumulation will lead to faults of transmission lines:

$$P = {\int }_{{t}_{3}}^{{t}_{4}} {e}^{- {λ}_{H d} ( {t}_{{4}^{-}} {t}_{3} )} [ {\sum }_{k = 1}^{K} \frac{H {d}_{k}}{{σ}_{k}} exp ( - \frac{{( H {d}_{{k}^{-}} {μ}_{k} )}^{2}}{2 {σ}_{k}^{2}} ) ] d t$$

when P increases, the hazard state of the transmission lines becomes more severe, wherein P represents the comprehensive hazard state determination value of the transmission lines at time t, t₃ is the initial time of the prediction period, t₄ is the termination time of the prediction period, λ_{Hd} is the decay coefficient of the hazard over time, K is the number of hazard feature values, Hdₖ is the i-th hazard feature value, σₖ is the standard deviation of the i-th hazard feature value, and μₖ is the average of the i-th hazard feature value.

As a preferred scheme of the method for identifying the discharge hazards of the transmission lines, wherein the comprehensive condition determination comprises: when the system acquires a new high-frequency discharge waveform, acquiring the new discharge hazard waveform y, extracting F features, and converting the features into F feature interval values S₁(y), S₂(y), . . . , S_{F}(y); in accordance with the rules of the hazard identification requirement table, looking up the table to find the maximum values in the rows of the feature intervals and comparing same to find the maximum value, the column of the maximum value corresponding to the discharge severity level E value, i.e., the severity level of the new discharge hazard waveform; and performing determination in combination with the comprehensive condition of the transmission lines:

When the new quantification value E is lower than 1 and the P value decreases, the current hazard level is low and shows a long-term decreasing trend, requiring continued monitoring and regular maintenance.

When the new quantification value E is lower than 1 and the P value increases, the current hazard level is low but shows a long-term increasing trend. It is regarded that no fault will occur within the prediction period and that the fault period will be delayed, the level B alarm is made, and local inspection and local maintenance are performed.

When the new quantification value E is greater than 1 and the P value decreases, the current hazard level is severe but shows a long-term decreasing trend. It is regarded that a fault will occur to the transmission lines within the prediction period. The level D alarm is made, and immediate repair is performed, and the long-term trend is re-predicted until the hazard event shows a decreasing trend.
when the new quantification value E is greater than 1 and the P value increases, the current hazard level is severe and shows a long-term increasing trend; the transmission lines will be subject to faults before the prediction period, the level G alarm is made, operation is immediately stopped, and maintenance measures are taken for intervention.

Another objective of the present invention is to provide a system for identifying discharge hazards of transmission lines. By means of real-time monitoring and analysis of discharge hazard data of the transmission lines, the hazard state of the lines is accurately identified and evaluated, early warning is sent timely, and a basis is provided for maintenance and repair of the lines, so that the safe and stable operation of the transmission lines is ensured.

As a preferred scheme of the system for identifying discharge hazards of transmission lines of the present invention, wherein the system comprises a data acquisition and processing module, a hazard identification requirement table module and an early warning and state evaluation module.

The data acquisition and processing module is used for acquiring measured data of discharge hazards of transmission lines, including hazard high-frequency discharge waveform data and discharge hazard event data, processing the hazard high-frequency discharge waveform data, extracting key features, creating a feature interval matrix, processing the discharge hazard event data and creating a hazard severity level sequence.

The hazard identification requirement table module is used for creating a hazard identification requirement table according to the feature interval matrix and the hazard severity level sequence, updating all elements in the table in the time sequence, determining operation and maintenance requirement levels corresponding to newly acquired discharge waveforms, and performing comprehensive determination and early warning on the hazard state of the lines.
the early warning and state evaluation module is used for evaluating the activity of hazard events based on discharge intervals according to the system identification model, calculating the current hazard value and the comprehensive condition determination value of the transmission lines, and in accordance with the evaluation results, performing early warnings of different levels and taking corresponding maintenance and repair measures.

A computer device, comprising a memory and a processor, wherein the memory stores a computer program, and the processor implements the steps in the method for identifying discharge hazards of the transmission lines when executing the computer program.

A computer-readable storage medium, on which a computer program is stored, wherein the computer program, when executed by the processor, implements the steps in the method for identifying discharge hazards of the transmission lines.

The present invention has the beneficial effects as follows: the advantages of the present invention are reflected in three aspects: firstly, the development process of potential hazards of the transmission lines can be taken into full account, particularly for nonlinear developments such as insulation deterioration and foreign object suspension, the discharge trend is difficult to predict, which may terminate without tripping, or may develop too rapidly, leading to situations difficult to predict in the prior art. Therefore, the accuracy and reliability are higher. Secondly, the present invention fully integrates known degree indicators of discharge hazards into the parameter matrix. Compared with existing methods that utilize machine learning or deep learning, the present invention provides higher interpretability and observability during implementation, and is therefore suitable for guiding line operation, maintenance, and repair; thirdly, the identification method provided in the present invention has a simple and clear implementation process, and compared with methods based on deep learning, the identification method has low requirement on data volume, low demand on hardware computing power, and wider application range.

In addition, in the present invention, a potential hazard early-warning requirement table is created, by means of special design of the updating process of the elements in the table, the functional requirement from discharge data to hazard identification is realized, and by fully combining historical data with future data, the reliability and reference value of the identification are further improved.

### BRIEF DESCRIPTION OF DRAWINGS

In order to more clearly illustrate the technical schemes of the embodiments of the present invention, the following will briefly introduce the drawings required in the embodiments. Apparently, the drawings described below are merely some embodiments of the present invention, for a common person skilled in the art, other drawings can also be obtained according to these drawings without creative labor.

FIG. 1 is an overall flowchart of the method for identifying discharge hazards of transmission lines provided in one embodiment of the present invention.

FIG. 2 is a flowchart of the system scheme of the method for identifying discharge hazards of transmission lines provided in one embodiment of the present invention.

### DETAILED DESCRIPTION OF THE EMBODIMENTS

In order to make the above objects, features and advantages of the present invention more obvious and easy to understand, the detailed description of the present invention will be illustrated in details below in conjunction with the drawings of the specification. Clearly, the described embodiments are part of the embodiments of the present invention, but not all. On the basis of the embodiments of the present invention, all other embodiments obtained by those of ordinary skill in the art without creative efforts shall fall within the protection scope of the present invention.

In the following description, numerous specific details are set forth in order to provide a thorough understanding of the present invention. However, the present invention may also be implemented in other ways different from the description herein. Those skilled in the art may make similar modifications without departing from the spirit of the present invention. Therefore, the present invention is not limited to the specific embodiments disclosed below.

Secondly, the term “one embodiment” or “embodiment,” as referred herein, refers to a particular feature, structure, or characteristic included in at least one implementation of the present invention. It should be understood that the appearances of the phrase “in one embodiment” in various places in the specification do not necessarily all refer to the same embodiment, nor are those independently or selectively exclusive of other embodiments.

The present invention is described in detail in conjunction with schematic diagrams. For the purpose of description, sectional views of the device structure are partially enlarged without being drawn to scale. The schematic diagrams are merely exemplary and should not limit the protection scope of the present invention. Furthermore, it is important to consider the three-dimensional spatial dimensions of length, width, and depth in actual production.

It should be noted that in the description of the present invention that terms such as “up, down, inside, and outside” indicating orientation or positional relationships are based on the orientation or positional relationships shown in the illustrations for the purpose of facilitating the description and simplifying the disclosure. They do not indicate or imply that the device or the components referred to must have a specific orientation, be constructed in a specific orientation, or operate in a specific orientation, and therefore should not be construed as limiting the present invention. In addition, the terms “first, second or third” are merely used for descriptive purposes and should not be construed as indicating or implying relative importance.

Unless otherwise explicitly defined or limited, the terms “mounted,” “connected,” or “coupled” in the present invention should be understood in a broad sense. For example, they can refer to a fixed connection, a detachable connection, or an integral connection; similarly, they can refer to a mechanical connection, an electrical connection, or a direct connection, or can be an indirect connection via an intermediate medium and can also be the communication in two components. The terms described above have specific meanings in the present invention that can be understood by those skilled in the art in light of the particular circumstances.

### Example 1

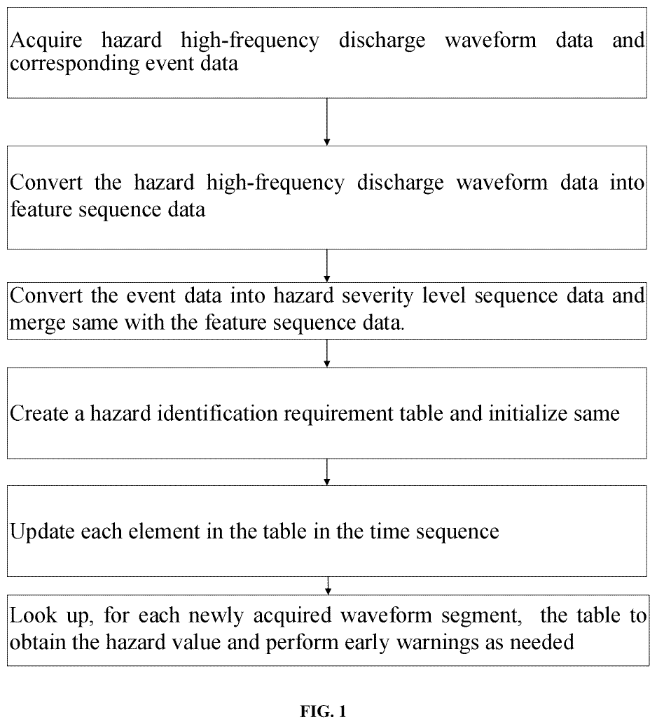

Referring to FIG. 1, a first embodiment of the present invention. The embodiment provides a method for identifying discharge hazards of transmission lines, comprising
S1: acquiring measured data of discharge hazards of the transmission lines, acquiring and processing hazard high-frequency discharge waveform data of the transmission lines, and acquiring and processing discharge hazard event data of the transmission lines;

Furthermore, the acquiring of the measured data of the discharge hazards of the transmission lines includes acquiring hazard high-frequency discharge waveform data and discharge hazard event data.

The hazard high-frequency discharge waveform data comprises segmenting the hazard high-frequency discharge waveform data into N short waveforms every 10 ms, i.e., half a power-frequency cycle, and calculating F key features Z₁ . . . Zᵢ . . . Z_{F} for each short waveform, for example, F=2, i.e., two features are calculated, wherein Z is the maximum amplitude in the short waveform, Z₂ is the power-frequency phase at which the maximum amplitude occurs.

Where, Z₁ is the maximum amplitude in the short waveform, Z_{F} is the power-frequency phase at which the maximum amplitude occurs; the maximum value Z_{i,max} and the minimum value Z_{i,min} are extracted from the current feature set of all short waveforms for each feature Zᵢ; the maximum and minimum values of the amplitudes of all the short waveforms are Z_{1,max} and Z_{1,min} for the amplitude feature Z₁, where (1)-(n) are the numbers of the short waveforms:

$${Z}_{i , max} = max ( {Z}_{i} ( 1 ) , {Z}_{i} ( 2 ) , … , {Z}_{i} ( n ) )$$

$${Z}_{i , min} = min ( {Z}_{i} ( 1 ) , {Z}_{i} ( 2 ) , … , {Z}_{i} ( n ) )$$

For example, with respect to the amplitude feature Z₁, the maximum and minimum values of the amplitudes of all the short waveforms are Z_{1,max} and Z_{1,min} respectively:

$${Z}_{1 , max} = max ( {Z}_{1} ( 1 ) , {Z}_{1} ( 2 ) , … , {Z}_{1} ( n ) )$$

$${Z}_{1 , min} = min ( {Z}_{1} ( 1 ) , {Z}_{1} ( 2 ) , … , {Z}_{1} ( n ) )$$

Similarly, with respect to the phase feature Z₂, the maximum value of the phases of all the short waveforms is Z_{2,max}, and the minimum value is Z_{2,min}.
discretization intervals are created to equally divide the range from the minimum value to the maximum value into Yᵢ intervals based on the minimum and maximum of each feature Zᵢ:

$$[ {Z}_{i , min} , {Z}_{i , min} + {Z}_{id} ) , [ {Z}_{i , min} + {Z}_{id} , {Z}_{i , min} + 2 \times {Z}_{id} ) , … ,$$

$$[ {Z}_{i , min} + ( {Y}_{{i}^{-}} 1 ) \times {Z}_{id} , {Z}_{i , max} ]$$

$${Z}_{id} = ( {Z}_{i , {max}^{-}} {Z}_{i , min} ) / {Y}_{i}$$

Where, Z_{id} is the interval width.

For example, with respect to the amplitude feature Z₁, three discretization intervals are created, Y₁=3, which are respectively:

$${Z}_{1 , min} , {Z}_{1 , min} + {Z}_{1 d} ) , [ {Z}_{1 , min} + {Z}_{1 d} , {Z}_{1 , min} + 2 \times {Z}_{1 d} ) , … ,$$

$$[ {Z}_{1 , min} + ( {Y}_{{1}^{-}} 1 ) \times {Z}_{1 d} , {Z}_{1 , max} ]$$

$${Z}_{1 d} = ( {Z}_{1 , {max}^{-}} {Z}_{1 , min} ) {/}_{3}$$

Similarly, three discretization intervals (Y₂=3): [Z_{2,min}, Z_{2,min}+Z_{2d}), [Z_{2,min}+Z_{2d}, Z_{2,min}+2×Z_{2d}), [Z_{2,min}+(Y₂−1)×Z_{2d},Z_{2,max}] of phase values are created.

The sum of the quantities of all the intervals for all the features is recorded as N,N=Y₁+Y₂+ . . . . Yᵢ+ . . . +Y_{F}, for example, in the previous examples, for N=3+3=6, an interval number set S=[1, 2, . . . , N], a total of N elements, is created, where each element is corresponding to a discretization interval.

For example, 1, 2, and 3 respectively represent the three intervals of the amplitude feature Zᵢ and 4, 5, and 6 respectively represent the three intervals of the phase Z₂. If the amplitude of a certain waveform is 1, and the three created amplitude intervals are [−1, 0), [0, 1), and [1, 2], then the feature belongs to the third in the amplitude interval, Si(j)=3.

As another example, if the phase feature of a certain waveform is −π/2, and the three created phase intervals are [−π, −π/3), [−π/3, π/3), and [π/3, π], then the feature belongs to the first in the phase interval, and also the fourth in set S, Sᵢ₍ⱼ₎₌4.
the key feature of each short waveform, the i-th feature Zᵢ(n) of the n-th short waveform, is converted into the corresponding S value of the interval; and a new feature interval matrix C is formed based on the interval S values generated by all F features of all n waveforms:

$$C \text{?} = [ \begin{matrix}{S}_{1 ( 1 )} & {S}_{1 ( 2 )} & … & {S}_{1 ( n )} \\ {S}_{2 ( 1 )} & {S}_{2 ( 2 )} & … & {S}_{2 ( n )} \\ … & … & … & … \\ {S}_{F ( 1 )} & {S}_{F ( 2 )} & … & {S}_{F ( n )}\end{matrix} ]$$

$$\text{?} \text{indicates text missing or illegible when filed}$$

each column of the matrix C represents the feature interval corresponding to all the features of one waveform, and each row represents the feature interval of all waveforms under any one feature type, the columns are arranged in the sequence of waveform acquisition, and the acquisition time of the left column is earlier than the waveform acquisition time represented by the right column for the waveform represented by the left column.

It should be noted that the acquiring of a set W=[W₁, W₂, . . . , Wₘ] of the discharge hazard event data of the transmission lines, where, 1−m are the number of the data, the time span covered by the data includes the time span covered by the discharge waveform data, the waveforms correspond to the known hazard events within the time: W₁ is the initiation of discharge caused by contamination accumulation on an insulator; W₂ is the further intensified discharge caused by burning of a suspended foreign object and the initiation of discharge due to excessive vegetation height; W₃ is the fault tripping caused by insulator degradation and failure; and W₄ is the clearance of a fault and the restoration of power supply by patrol personnel.

The hazard severity level sequence data includes a hazard severity level quantification value E, within the range of 0-4, assigned to each known hazard event in accordance with actual line operation and maintenance requirements, with the level range set in a range of 0, 1, 2, and 3: E=0 indicates no discharge hazard phenomenon.

E=1 indicates slight discharge, requiring continued monitoring.

E=2 indicates moderate discharge, which will cause flashover tripping and require partial inspection during line patrol.

E=3 indicates very severe discharge, which has already caused fault tripping and requires immediate proactive repair.

W₁ is the initiation of discharge caused by contamination accumulation on an insulator, belonging to the early-stage hazard with slight level, E₁=1.

W₂ is the further intensified discharge caused by burning of a suspended foreign object and the initiation of discharge due to excessive vegetation height, resulting in a fault over an extended period, E₂=2.

W₃ is the fault tripping caused by insulator degradation and failure, which has already caused tripping and requires immediate repair, E₃=3.

W₄ is the clearance of a fault and the restoration of power supply by patrol personnel, in which hazards are eliminated and there are no events, E₄=0.
the hazard level sequence formed is E=[1, 2, 3, 0].

It should also be noted that the activity of hazard events is evaluated based on the discharge interval:

$$f ( t ) = {\int }_{{t}_{1}}^{{t}_{2}} ( {\sum }_{j = 1}^{J} E \cdot \frac{{e}^{- {λ}_{j} ( t - {t}_{j} )}}{{λ}_{j}} ) dt + {\int }_{{t}_{1}}^{{t}_{2}} Φ ( \frac{Δ ( {t}^{′} ) - \overline{Δ}}{{σ}_{Δ}} ) {dt}^{′}$$

where n represents the number of discharge events occurring within the evaluation period, E is the severity level of the hazard events, λⱼ is the attenuation rate of the j-th discharge event, t₁ and t₂ are the start and end time of the evaluation period, tⱼ is the time at which the j-th discharge event occurs, Φ represents the standardization of the discharge interval difference, Δ(t′) represents the discharge interval at time t′, Δ̅ represents the average of the discharge interval, and σ_{Δ} represents the standard deviation of the discharge interval.

When Φ stabilizes between 0.45 and 0.55, the frequency and severity of discharge events are consistent with the average level, requiring continued monitoring. When Φ exceeds 0.55, the discharge interval is longer than the average time, the flash of a green light indicates that the activity of the hazard event is weakening.

When Φ is lower than 0.45, the discharge interval is shorter than the average time, and an A-level alarm is made, indicating that the activity of the current hazard event is increasing.
when F(t) decreases, the discharge event occurs but at a reduced frequency, indicating that the hazard event has been accumulated over a long period and may result in a fault of a transmission line, and a B-level alarm is made for hazard identification requirements to notify workers to conduct maintenance and inspection;
when F(t) increases, the discharge event occur frequently, indicating that the development of the current hazard event in a short term may cause a transmission line fault, and a D-level alarm is made to create current hazard identification requirements for the current hazard events and perform immediate repair.
S2: creating a hazard identification requirement table and initializing same, and updating all elements in the table in a time sequence.

Furthermore, the rules of the hazard identification requirement table are as follows: the table includes a rows and b columns, a is the number of feature intervals derived from discharge hazard waveform data, b is the number of discharge severity level derived from discharge hazard event data, and the initial values of all elements are the corresponding level value E in the columns where the elements are located. when a particular feature of the waveform falls within the feature interval represented by a, the discharge severity level at the current moment is the operation and maintenance requirement level represented by b. The maximum value in the current row represents the most urgent operation and maintenance action for the current feature interval. When F>1, i.e., the same waveform includes multiple features, the maximum values of all rows are compared, and the largest value is taken as the operation and maintenance requirement level of the current waveform.

For example, according to the previous example, the table comprises 6 rows and 4 columns. If the amplitude of the x-th waveform is 1, the feature interval value S₁(x)=3. corresponding to the third row of the table. Assume the four values in this row are [1, 5, 15, 2], where the third value, 15, is the maximum. This indicates that the discharge severity level corresponding to an amplitude of 1 is level 2 (the third in the level range 0, 1, 2, 3).

If the phase feature interval of the waveform is S₂(x)=4, and the four values in the fourth row are [11, 9, 8, 2], where the first value, 11, is the maximum, then the phase feature corresponds to the first severity level 0.

By comparing the maximum values of the rows corresponding to the two feature intervals, it can be seen that 15>11. The larger value is taken, and thus the overall discharge severity level corresponding to the waveform is 2.

The earliest collected short waveform u and the waveform v at the next time are collected based on the feature interval matrix C. In combination with the hazard identification requirement table, the feature interval value Sᵢ(u) of the feature i of the waveform u represents the row, while the corresponding value Eu of the waveform represents the column. The element at the intersection of the row Sᵢ(u) and the column Eu in the table represents the operation and maintenance requirement level of the feature i of the waveform u with the corresponding discharge level Eu, denoted table element as T (Sᵢ(u), Eu).
the table element T′ (Sᵢ(u), Eu) is updated for each feature i:

$${T}^{′} ( {S}_{i} ( u ) , Eu ) = 0.9 \times T ( {S}_{i} ( u ) , Eu ) + 0 \text{.8} \times Ev - T ( {S}_{i} ( u ) , Eu ) )$$

Where 0.9 represents the guiding effect of historical identical discharge hazard features on labeling the hazard severity of added discharge, and 0.8 represents the predictive significance of future discharge hazards within the same discharge waveform in labeling the current severity.
in the acquisition time sequence, each waveform and the waveform at the next time in the subsequent time are updated in table elements, until all the waveforms are processed and the table is fully filled.

S3: Looking up, for each newly acquired waveform segment, the table to determine the operation and maintenance requirement level corresponding to the newly acquired discharge waveform, and performing comprehensive determination and early warning on the hazard state of the lines.

Furthermore, the current hazard value Hd is calculated:

$$Hd = \frac{{\int }_{0}^{D} B \cdot {e}^{- α t}}{Norm {\sum }_{m = 1}^{M} Filter ( {d}_{m} , β )}$$

The larger Hd indicates the more severe hazard, the smaller Hd indicates the less severe hazard, where B represents the discharge amplitude, dₘ represents the discharge waveform, M represents the number of waveform parameters, α and β are parameters adjusted according to actual conditions to control the intensity of exponential attenuation and information filtering, Norm represents the normalization of the summation result, and Filter is used for filtering waveform shape parameters;
the comprehensive condition of the transmission lines is determined after predicting that the long-term accumulation will lead to faults of transmission lines:

$$P = {\int }_{{t}_{3}}^{{t}_{4}} {e}^{- {λ}_{Hd} ( {t}_{4 -} {t}_{3} )} [ {\sum }_{k = 1}^{K} \frac{{Hd}_{k}}{{σ}_{k}} exp ( - \frac{{( {Hd}_{{k}^{-}} {μ}_{k} )}^{2}}{2 {σ}_{k}^{2}} ) ] dt$$

when P increases, the hazard state of the transmission lines becomes more severe, wherein P represents the comprehensive hazard state determination value of the transmission lines at time t, t₃ is the initial time of the prediction period, t₄ is the termination time of the prediction period, λ_{Hd} is the decay coefficient of the hazard over time, K is the number of hazard feature values, Hdₖ is the i-th hazard feature value, σₖ is the standard deviation of the i-th hazard feature value, and μₖ is the average of the i-th hazard feature value.

It should be noted that when the system acquires a new high-frequency discharge waveform, comprising: acquiring the new discharge hazard waveform y, extracting F features, and converting the features into F feature interval values S₁(y), S₂(y), . . . , S_{F}(y); in accordance with the rules of the hazard identification requirement table, looking up the table to find the maximum values in the rows of the feature intervals and comparing same to find the maximum value, the column of the maximum value corresponding to the discharge severity level E value, i.e., the severity level of the new discharge hazard waveform; and performing determination in combination with the comprehensive condition of the transmission lines:

When the new quantification value E is lower than 1 and the P value decreases, the current hazard level is low and shows a long-term decreasing trend, requiring continued monitoring and regular maintenance.

When the new quantification value E is lower than 1 and the P value increases, the current hazard level is low but shows a long-term increasing trend. It is regarded that no fault will occur within the prediction period and that the fault period will be delayed, the level B alarm is made, and local inspection and local maintenance are performed.

When the new quantification value E is greater than 1 and the P value decreases, the current hazard level is severe but shows a long-term decreasing trend. It is regarded that a fault will occur to the transmission lines within the prediction period. The level D alarm is made, and immediate repair is performed, and the long-term trend is re-predicted until the hazard event shows a decreasing trend.
when the new quantification value E is greater than 1 and the P value increases, the current hazard level is severe and shows a long-term increasing trend; the transmission lines will be subject to faults before the prediction period, the level G alarm is made, operation is immediately stopped, and maintenance measures are taken for intervention.

It should be noted that the above embodiment is merely used for illustrating the technical scheme of the present invention instead of limitations thereto; although the present invention is illustrated in detail with reference to the above example, those ordinarily skilled in the art should understand that the technical scheme of the present invention can be modified or equivalently substituted without departing from the spirit and scope of the technical scheme of the present invention. Such modifications and substitutions are intended to be encompassed within the scope of the claims of the present invention.

### Embodiment 2

A second embodiment of the present invention provides a method for identifying discharge hazards of transmission lines. To verify the beneficial effects of the present invention, scientific validation is conducted via experiments.

First, high-frequency discharge waveform data of the transmission lines under normal operating conditions were collected, and relevant discharge event data were recorded. These data were used for creating an initial hazard identification requirement table.

The collected waveform data were segmented into multiple short waveforms at intervals of 10 ms, and F key features were calculated for each short waveform. These features include the maximum amplitude, the power frequency phase and the like in the short waveform; based on the acquired data, the hazard identification requirement table was initialized, and all elements of the table were updated in the time sequence. For each newly acquired waveform segment, the corresponding operation and maintenance requirement level was determined by table lookup, and comprehensive determination and early warning onthe hazard state of the transmission lines were performed.

During the data acquisition and processing, feature values, sequence data of hazard severity levels and discharge interval evaluation results of different discharge events were recorded, as shown in Table 1.

TABLE 1

| | | | | Standard | |
|---|---|---|---|---|---|
| | Number | | Average | Deviation | Comprehensive |
| | of | Discharge | Value of | of | Hazard State |
| | Discharge | Severity | Discharge | Discharge | Determination |
| Test Objects | Events | Level | Interval | Interval | Value |
| Transmission Line A | 15 | 1.5 | 0.5 | 0.1 | 0.75 |
| Transmission Line B | 25 | 2 | 0.45 | 0.15 | 0.85 |
| Transmission Line C | 10 | 3 | 0.55 | 0.05 | 0.9 |

On Transmission Line C, the discharge severity level and the comprehensive hazard state determination value are high, indicating the presence of more serious potential hazards on this line. By means of the method of the present invention, these hazards can be identified and warned more accurately, and thus, operation and maintenance efficiency and safety are improved.

It should be noted that the above embodiment is merely used for illustrating the technical scheme of the present invention instead of limitations thereto; although the present invention is illustrated in detail with reference to the above example, those ordinarily skilled in the art should understand that the technical scheme of the present invention can be modified or equivalently substituted without departing from the spirit and scope of the technical scheme of the present invention. Such modifications and substitutions are intended to be encompassed within the scope of the claims of the present invention.

### Embodiment 3

A third embodiment of the present invention is different from the front two embodiments in that:

If a function is implemented in a form of a software functional unit, and sold or used as an independent product, the function may be stored in a computer-readable storage medium. Based on such understanding, the technical scheme of the present invention, in essence or in terms of the part contributing to the prior art, or part of the technical scheme, can be embodied in the form of a software product. The computer software product is stored in a storage medium and comprises a plurality of instructions to enable a computer device (such as a personal computer, a server, or a network device, etc.) to execute all or part of the steps of the method described in the various embodiments of the present invention. The aforementioned storage medium includes, but is not limited to, USB drives, portable hard disks, read-only memory (ROM), Random Access Memory (RAM), magnetic disks, optical disks, or any other media capable of storing program codes.

Logics and/or steps expressed in the flow diagram or otherwise described herein, for example, may be considered as an ordered list of executable instructions used for realizing logical functions, and may be specifically realized in any computer-readable medium for being used by instruction execution systems, apparatuses, or devices (such as computer-based systems, systems including processors, or other systems that may acquire instructions from the instruction execution systems, the apparatuses, or the devices and execute the instructions), or used in conjunction with these instruction execution systems, apparatuses, or devices. With regard to the present specification, the “computer-readable medium” may be any apparatus that may include, store, communicate, propagate or transmit a program for being used by the instruction execution systems, the apparatuses, or the devices, or used in conjunction with these instruction execution systems, apparatuses, or devices.

More specific instances of the machine-readable storage medium (non-exhaustive list) include: an electric connection part (an electronic apparatus) with one or more wires, a portable computer disk case (a magnetic apparatus), a random access memory (RAM), a read-only memory (ROM), an erasable programmable read-only memory (EPROM or a flash memory), an optical fiber apparatus, and a portable compact disk read-only memory (CDROM). In addition, the computer-readable medium may even be paper or other appropriate media in which the program may be printed, due to that the program may be obtained in an electronic manner, for example, through optically scanning the paper or the other media, and then editing, interpreting or processing in other appropriate manners if necessary, and then the program is stored in a computer memory.

It should be understood that, each part of the present invention may be realized by hardware, software, firmware or a combination thereof. In the above implementation manners, a plurality of steps or methods may be realized by software or firmware stored in the memory and executed by the appropriate instruction execution systems. For example, if the plurality of steps or methods are realized by hardware, as in another implementation manner, the plurality of steps or methods may be realized by any one of the following technologies which are well known in the art or a combination thereof: a discrete logic circuit with a logic gate circuit for realizing a logic function for a data signal, an application-specific integrated circuit with an appropriate combinational logic gate circuit, a programmable gate array (PGA), a field-programmable gate array (FPGA), etc.

### Embodiment 4

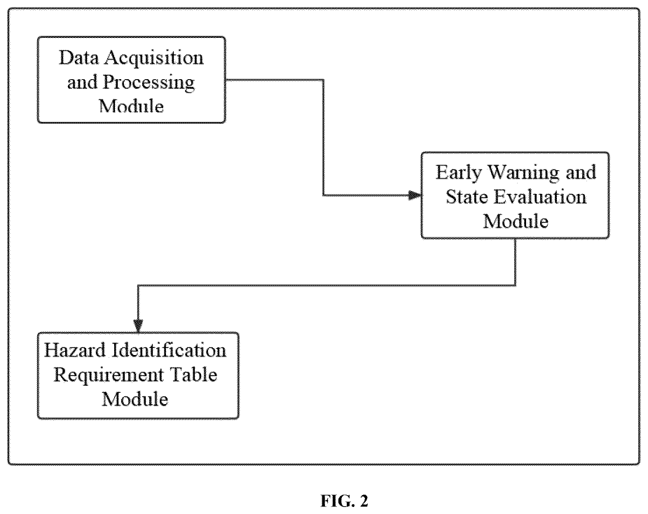

Referring to FIG. 2, a fourth embodiment of the present invention provides a system for identifying discharge hazards of transmission lines, comprising a data acquisition and processing module, a hazard identification requirement table module and an early warning and state evaluation module.

The data acquisition and processing module is used for acquiring measured data of discharge hazards of transmission lines, including hazard high-frequency discharge waveform data and discharge hazard event data, processing the hazard high-frequency discharge waveform data, extracting key features, creating a feature interval matrix, processing the discharge hazard event data and creating a hazard severity level sequence.

The hazard identification requirement table module is used for creating a hazard identification requirement table according to the feature interval matrix and the hazard severity level sequence, updating all elements in the table in the time sequence, determining operation and maintenance requirement levels corresponding to newly acquired discharge waveforms, and performing comprehensive determination and early warning on the hazard state of the lines.

The early warning and state evaluation module is used for evaluating the activity of hazard events based on discharge intervals according to the system identification model, calculating the current hazard value and the comprehensive condition determination value of the transmission lines, and in accordance with the evaluation results, performing early warnings of different levels and taking corresponding maintenance and repair measures.

It should be noted that the above embodiment is merely used for illustrating the technical scheme of the present invention instead of limitations thereto; although the present invention is illustrated in detail with reference to the above example, those ordinarily skilled in the art should understand that the technical scheme of the present invention can be modified or equivalently substituted without departing from the spirit and scope of the technical scheme of the present invention. Such modifications and substitutions are intended to be encompassed within the scope of the claims of the present invention.

What is claimed is:

1. A method for identifying discharge hazards of transmission lines, wherein the method comprises:
acquiring measured data of discharge hazards of the transmission lines, acquiring and processing hazard high-frequency discharge waveform data of the transmission lines, and acquiring and processing discharge hazard event data of the transmission lines;
creating a hazard identification requirement table and initializing same, and updating all elements in the table in a time sequence; and
looking up, for each newly acquired waveform segment, the table to determine the operation and maintenance requirement level corresponding to the newly acquired discharge waveform, and performing comprehensive determination and early warning on the hazard state of the lines.

2. The method for identifying the discharge hazards of the transmission lines according to claim 1, wherein the acquiring measured data of discharge hazards of the transmission lines comprises acquiring the hazard high-frequency discharge waveform data and the discharge hazard event data;
the hazard high-frequency discharge waveform data comprises segmenting the hazard high-frequency discharge waveform data into N short waveforms every 10 ms, i.e., half a power-frequency cycle, and calculating F key features Z₁ . . . . Zᵢ . . . . Z_{F} for each short waveform, wherein Z₁ is the maximum amplitude in the short waveform, Z_{F} is the power-frequency phase at which the maximum amplitude occurs; the maximum value Z_{i,max} and the minimum value Z_{i,min} are extracted from the current feature set of all short waveforms for each feature Zᵢ; the maximum and minimum values among the amplitudes of all short waveforms are Z_{1,max} and Z_{1,min} for the amplitude feature Z₁, wherein (1)-(n) are the numbers of the short waveforms:
$${Z}_{i , max} = max ( {Z}_{i} ( 1 ) , {Z}_{i} ( 2 ) , … , {Z}_{i} ( n ) )$$
$${Z}_{i , min} = min ( {Z}_{i} ( 1 ) , {Z}_{i} ( 2 ) , … , {Z}_{i} ( n ) )$$
discretization intervals are created to equally divide the range from the minimum value to the maximum value into Yᵢ intervals based on the minimum and maximum of each feature Zᵢ:
$$[ {Z}_{i , min} , {Z}_{i , min} + {Z}_{id} ) , [ {Z}_{i , min} + {Z}_{id} , {Z}_{i , min} + 2 \times {Z}_{id} ) , … ,$$
$$[ {Z}_{i , min} + ( {Y}_{{i}^{-}} 1 ) \times {Z}_{id} , {Z}_{i , max} ]$$
$${Z}_{id} = ( {Z}_{i , {max}^{-}} {Z}_{i , min} ) / {Y}_{i}$$
wherein, Z_{id} is the interval width;
the sum of the quantities of all the intervals for all the features is recorded as N, N=Y₁+Y₂+ . . . . Yᵢ+ . . . +Y_{F}, and an interval number set S=[1, 2, . . . , N], a total of N elements, is created, wherein each element is corresponding to a discretization interval;
the key feature of each short waveform, the i-th feature Zᵢ(n) of the n-th short waveform, is converted into the corresponding S value of the interval; and a new feature interval matrix C is formed based on the interval S values generated by all F features of all n waveforms:
$$C \text{?} = [ \begin{matrix}{S}_{1 ( 1 )} & {S}_{1 ( 2 )} & … & {S}_{1 ( n )} \\ {S}_{2 ( 1 )} & {S}_{2 ( 2 )} & … & {S}_{2 ( n )} \\ … & … & … & … \\ {S}_{F ( 1 )} & {S}_{F ( 2 )} & … & {S}_{F ( n )}\end{matrix} ]$$
$$\text{?} \text{indicates text missing or illegible when filed}$$
each column of the matrix C represents the feature interval corresponding to all the features of one waveform, and each row represents the feature interval of all waveforms under any one feature type, the columns are arranged in the sequence of waveform acquisition, and the acquisition time of the left column is earlier than the waveform acquisition time represented by the right column for the waveform represented by the left column.

3. The method for identifying the discharge hazards of the transmission lines according to claim 2, wherein the discharge hazard event data comprises acquiring a set W=[W₁, W₂, . . . , Wₘ] of the discharge hazard event data of the transmission lines, wherein, 1-m are the number of the data, the time span covered by the data includes the time span covered by the discharge waveform data, the waveforms correspond to the known hazard events within the time: W₁ is the initiation of discharge caused by contamination accumulation on an insulator; W₂ is the further intensified discharge caused by burning of a suspended foreign object and the initiation of discharge due to excessive vegetation height; W₃ is the fault tripping caused by insulator degradation and failure; and W₄ is the clearance of a fault and the restoration of power supply by patrol personnel;
the hazard severity level sequence data includes a hazard severity level quantification value E, within the range of 0-4, assigned to each known hazard event in accordance with actual line operation and maintenance requirements, with the level range set in a range of 0, 1, 2, and 3: E=0 indicates no discharge hazard phenomenon;
E=1 indicates slight discharge, requiring continued monitoring;
E=2 indicates moderate discharge, which will cause flashover tripping and require partial inspection during line patrol;
E=3 indicates very severe discharge, which has already caused fault tripping and requires immediate proactive repair;
W₁ is the initiation of discharge caused by contamination accumulation on an insulator, belonging to the early-stage hazard with slight level, E₁=1;
W₂ is the further intensified discharge caused by burning of a suspended foreign object and the initiation of discharge due to excessive vegetation height, resulting in a fault over an extended period, E₂=2;
W₃ is the fault tripping caused by insulator degradation and failure, which has already caused tripping and requires immediate repair, E₃=3;
W₄ is the clearance of a fault and the restoration of power supply by patrol personnel, in which hazards are eliminated and there are no events, E₄=0;
the hazard level sequence formed is E=[1, 2, 3, 0].

4. The method for identifying the discharge hazards of the transmission lines according to claim 3, wherein the acquiring and processing discharge hazard event data of the transmission lines comprises evaluating the activity of the hazard events based on the discharge interval through a system identification model:
$$f ( t ) = {\int }_{{t}_{1}}^{{t}_{2}} ( {\sum }_{j = 1}^{J} E \cdot \frac{{e}^{- {λ}_{j} ( t - {t}_{j} )}}{{λ}_{j}} ) dt + {\int }_{{t}_{1}}^{{t}_{2}} Φ ( \frac{Δ ( {t}^{′} ) - \overline{Δ}}{{σ}_{Δ}} ) {dt}^{′}$$
wherein n represents the number of discharge events occurring within the evaluation period, E is the severity level of the hazard events, λⱼ is the attenuation rate of the j-th discharge event, t₁ and t₂ are the start and end time of the evaluation period, tⱼ is the time at which the j-th discharge event occurs, Φ represents the standardization of the discharge interval difference, Δ(t′) represents the discharge interval at time t′, Δ̅ represents the average of the discharge interval, and σ_{Δ} represents the standard deviation of the discharge interval;
when Φ stabilizes between 0.45 and 0.55, the frequency and severity of discharge events are consistent with the average level, requiring continued monitoring; when Φ exceeds 0.55, the discharge interval is longer than the average time, the flash of a green light indicates that the activity of the hazard event is weakening;
when Φ is lower than 0.45, the discharge interval is shorter than the average time, and an A-level alarm is made, indicating that the activity of the current hazard event is increasing;
when F(t) decreases, the discharge event occurs but at a reduced frequency, indicating that the hazard event has been accumulated over a long period and may result in a fault of a transmission line, and a B-level alarm is made for hazard identification requirements to notify workers to conduct maintenance and inspection;
when F(t) increases, the discharge event occur frequently, indicating that the development of the current hazard event in a short term may cause a transmission line fault, and a D-level alarm is made to create current hazard identification requirements for the current hazard events and perform immediate repair.

5. The method for identifying the discharge hazards of the transmission lines according to claim 4, wherein the creating a hazard identification requirement table includes the following rule for the hazard identification requirement table: the table comprises a rows and b columns, wherein a is the number of feature intervals derived from discharge hazard waveform data, b is the number of discharge severity level derived from discharge hazard event data, and the initial values of all elements are the corresponding level value E in the columns where the elements are located, indicating that when a particular feature of the waveform falls within the feature interval represented by a, the discharge severity level at the current moment is the operation and maintenance requirement level represented by b, the column represented by the maximum value in the current row is the most needed operation and maintenance action for the current feature interval, when F>1, i.e., the same waveform comprises multiple features, the maximum value in each row is compared, and the maximum value is taken as the operation and maintenance requirement level of the current waveform;
the earliest collected short waveform u and the waveform v at the next time are collected based on the feature interval matrix C, in combination with the hazard identification requirement table, the feature interval value Sᵢ(u) of the feature i of the waveform u represents the row, while the corresponding value Eu of the waveform represents the column, the element at the intersection of the row Sᵢ(u) and the column Eu in the table represents the operation and maintenance requirement level of the feature i of the waveform u with the corresponding discharge level Eu, denoted table element as T (Sᵢ(u), Eu);
the table element T′ (Sᵢ(u), Eu) is updated for each feature i:
$${T}^{′} ( {S}_{i} ( u ) , Eu ) = 0.9 \times T ( {S}_{i} ( u ) , Eu ) + 0 \text{.8} \times ( Ev - T ( {S}_{i} ( u ) , Eu ) )$$
wherein 0.9 represents the guiding effect of historical identical discharge hazard features on labeling the hazard severity of added discharge, and 0.8 represents the predictive significance of future discharge hazards within the same discharge waveform in labeling the current severity;
in the acquisition time sequence, each waveform and the waveform at the next time in the subsequent time are updated in table elements, until all the waveforms are processed and the table is fully filled.

6. The method for identifying the discharge hazards of the transmission lines according to claim 5, wherein the comprehensive determination and early warning on the hazard state of the lines comprises calculating the current hazard value Hd:
$$Hd = \frac{{\int }_{0}^{D} B \cdot {e}^{- α t}}{Norm {\sum }_{m = 1}^{M} Filter ( {d}_{m} , β )}$$
the larger Hd indicates the more severe hazard, the smaller Hd indicates the less severe hazard, wherein B represents the discharge amplitude, dₘ represents the discharge waveform, M represents the number of waveform parameters, α and β are parameters adjusted according to actual conditions to control the intensity of exponential attenuation and information filtering, Norm represents the normalization of the summation result, and Filter is used for filtering waveform shape parameters;
the comprehensive condition of the transmission lines is determined after predicting that the long-term accumulation will lead to faults of transmission lines:
$$P = {\int }_{{t}_{3}}^{{t}_{4}} {e}^{- {λ}_{Hd} ( {t}_{4 -} {t}_{3} )} [ {\sum }_{k = 1}^{K} \frac{{Hd}_{k}}{{σ}_{k}} exp ( - \frac{{( {Hd}_{{k}^{-}} {μ}_{k} )}^{2}}{2 {σ}_{k}^{2}} ) ] dt$$
when P increases, the hazard state of the transmission lines becomes more severe, wherein P represents the comprehensive hazard state determination value of the transmission lines at time t, t₃ is the initial time of the prediction period, t₄ is the termination time of the prediction period, λ_{Hd} is the decay coefficient of the hazard over time, K is the number of hazard feature values, Hdₖ is the i-th hazard feature value, σₖ is the standard deviation of the i-th hazard feature value, and μₖ is the average of the i-th hazard feature value.

7. The method for identifying the discharge hazards of the transmission lines according to claim 6, wherein the comprehensive condition determination comprises: when the system acquires a new high-frequency discharge waveform, acquiring the new discharge hazard waveform y, extracting F features, and converting the features into F feature interval values S₁(y), S₂(y), . . . , S_{F}(y); in accordance with the rules of the hazard identification requirement table, looking up the table to find the maximum values in the rows of the feature intervals and comparing same to find the maximum value, the column of the maximum value corresponding to the discharge severity level E value, i.e., the severity level of the new discharge hazard waveform; and performing determination in combination with the comprehensive condition of the transmission lines:
when the new quantification value E is lower than 1 and the P value decreases, the current hazard level is low and shows a long-term decreasing trend, monitoring is maintained and regular maintenance is performed;
when the new quantification value E is lower than 1 and the P value increases, the current hazard level is low but shows a long-term increasing trend, no fault will occur within the prediction period and that the fault period will be delayed, the level B alarm is made, and local inspection and partial maintenance are performed;
when the new quantification value E is greater than 1 and the P value decreases, the current hazard level is severe but shows a long-term decreasing trend, the transmission lines will be subject to faults within the prediction period, the level D alarm is made, immediate repair is performed, and the long-term trend is re-predicted until the hazard event shows a decreasing trend;
when the new quantification value E is greater than 1 and the P value increases, the current hazard level is severe and shows a long-term increasing trend; the transmission lines will be subject to faults before the prediction period, the level G alarm is made, operation is immediately stopped, and maintenance measures are taken for intervention.

8. A system for implementing the method for identifying discharge hazards of transmission lines according to claim 7, wherein the system comprises a data acquisition and processing module, a hazard identification requirement table module and an early warning and state evaluation module;
the data acquisition and processing module is used for acquiring measured data of discharge hazards of transmission lines, comprising hazard high-frequency discharge waveform data and discharge hazard event data, processing the hazard high-frequency discharge waveform data, extracting key features, creating a feature interval matrix, processing the discharge hazard event data and creating a hazard severity level sequence;
the hazard identification requirement table module is used for creating a hazard identification requirement table according to the feature interval matrix and the hazard severity level sequence, updating all elements in the table in the time sequence, determining operation and maintenance requirement levels corresponding to newly acquired discharge waveforms, and performing comprehensive determination and early warning on the hazard state of the line;
the early warning and state evaluation module is used for evaluating the activity of hazard events based on discharge intervals according to the system identification model, calculating the current hazard value and the comprehensive condition determination value of the transmission lines, and in accordance with the evaluation results, performing early warnings of different levels and taking corresponding maintenance and repair measures.

9. A computer device, comprising a memory in which a computer program is stored and a processor, wherein when the computer program is executed by the processor, the steps of the method according to claim 7 are implemented.

10. A computer-readable storage medium in which a computer program is stored, wherein when the computer program is executed by a processor, the steps of the method of claim 7 are implemented.
